(19) United States
(12) Patent Application Publication
(10) Pub. No.: US 2014/0162021 A1
(43) Pub. Date: Jun. 12, 2014

(54) METHOD FOR PRODUCING GRAPHENE, AND GRAPHENE PRODUCED BY THE METHOD

(71) Applicant: FUJI ELECTRIC CO., LTD., Kawasaki-shi (JP)

(72) Inventors: Takeshi FUJII, Hino-city (JP); Mariko SATO, Fujisawa-city (JP)

(73) Assignee: FUJI ELECTRIC CO., LTD., Kawasaki-shi (JP)

(21) Appl. No.: 14/178,570

(22) Filed: Feb. 12, 2014

Related U.S. Application Data
(63) Continuation of application No. PCT/JP2012/005647, filed on Sep. 6, 2012.

(30) Foreign Application Priority Data
Sep. 16, 2011 (JP) 2011-203514

(51) Int. Cl. C30B 25/18; C30B 29/02; C30B 29/68

(52) U.S. Cl. CPC C30B 25/183; C30B 29/68; C30B 29/02
USPC 428/141; 117/95; 428/408; 428/336; 428/164

(57) ABSTRACT

A method for producing grapheme is disclosed in which graphene is formed by supplying carbon to a heated transition metal surface, in order to form a high-quality uniform graphene film having no domain boundaries. The method includes forming a buffer thin film that is epitaxially grown on a Ni(111) substrate, and forming graphene on the buffer thin film. The buffer thin film is made of material selected from the group consisting of Fe, Co, Ni, Cu, Mo, Ru, Rh, Pd, W, Re, Ir and Pt, or from alloys thereof. The buffer thin film has a surface of three-fold symmetry or six-fold symmetry.

### BACKGROUND OF THE INVENTION

A. Field of the Invention

The present invention relates to a method for producing graphene, and to graphene. More particularly it relates to a method for producing graphene in which monolayer graphene is formed on a buffer thin film that is epitaxially formed on a Ni(111) single-crystal substrate, and also relates to graphene.

B. Description of the Related Art

Graphene is a sheet of carbon atoms that are arrayed within the same plane through bonding to each other via sp² bonds.

The following documents will now be discussed:

Non-Patent Document 1: K. S. Novoselov, A. K. Geim, S. V. Morozov, D. Jiang, Y. Zhang, S. V. Dubonos, I. V. Grigorieva, A. A. Firsov, Science 306 (2004) 666.

Non-Patent Document 2: K. S. Novoselov, D. Jiang, F. Schedin, T. J. Booth, V. V. Khotkevich, S. V. Morozov and A. K. Geim, Proc. Natl. Acad. Sci. USA. 102 (2005) 10451.

Non-Patent Document 3: Xuesong et al., Nano Lett. 9 (2009) 4359-4362.

In recent years the reported peculiar quantum conductance such as the half-integer Hall effect, derived from the two-dimensionality in the discovered monolayer graphene, has received considerable attention in the field of condensed-matter physics, as disclosed in Non-Patent Document 1 and Non-Patent Document 2.

Specifically, the mobility of graphene takes on a value of 15000 cm²/Vs, higher by an order of magnitude or more than that of silicon. Therefore, various industrial applications have been proposed for grapheme. These include, for instance, transistors that surpass Si, spin injection devices, and gas sensors that detect single molecules. Among the foregoing, the application of graphene to conductive thin films and transparent conductive films has become the object of active research and development.

Low sheet resistance is an important characteristic in conductive thin films. Sheet resistance is inversely proportional to conductivity and to film thickness, and hence the thicker the film, the lower the value of sheet resistance that can be obtained. Conductivity is proportional to mobility, and thus conductivity can be expected to improve through formation of graphene of higher film quality. For instance, Non-Patent Document 3 discloses the feature of forming a graphene thin film on a Cu foil, by CVD.

In the case where graphene is formed on a Cu foil by CVD, the Cu foil undergoes polycrystallization, since the Cu foil is heated at 1000° C. during CVD. The crystal orientations in the polycrystallized Cu foil are diverse, for instance (001), (111) and (110). Graphene growth is difficult to control herein since the growth rate of graphene varies depending on the crystal axis. As a result, graphene exhibits domain structures of several μm, and defects contaminate the graphene at domain boundaries, which gives rise to carrier scattering and lower graphene mobility.

Graphene is expected to form epitaxially in a case where a graphene film is formed on Ni(111) by CVD, since Ni(111), like graphene, has three-fold symmetry, and is the material that exhibits the smallest lattice mismatch, of about 1.2%, from among transition metals. Graphene of large domain size could thus be grown on Ni(111) as a result.

Solubility of carbon in Ni is high, and thus carbon that is supplied during film formation and that dissolves into Ni becomes supersaturated during cooling, is discharged on the surface, and graphene is grown as a result. The number of layers and the homogeneity of graphene thus grown are governed by the cooling rate, rather than by crystal orientation or mismatch, and it is thus difficult to form graphene of large domain size. Therefore, no substrates have succeeded thus far in combining low lattice mismatch with low carbon solubility.

Controlling the growth of graphene and forming graphene of small domain boundaries are major problems in industrial applications, in terms of controlling the quality of a graphene film and achieving a stable production.

The present invention is directed to overcoming or at least reducing the effects of one or more of the problems set forth above.

### SUMMARY OF THE INVENTION

The present invention forms a high-quality uniform graphene film having no domain boundaries.

The method for producing graphene and the graphene of the present invention involve, as a characterizing feature, forming a graphene film on a buffer thin film that is formed epitaxially on a Ni(111) single-crystal substrate. The buffer thin film is grown epitaxially with Ni(111), and hence the symmetry of the buffer thin film is identical to that of the crystal structure of graphene (three-fold symmetry or six-fold symmetry), and the same lattice mismatch with Ni(111) is preserved. Graphene is epitaxially grown as a result.

Also, the buffer thin film is formed epitaxially on the Ni(111) substrate, at the atomic level, and hence the buffer thin film exhibits no domain boundaries, and has an atomically flat surface. As a result, the graphene is grown uniformly, with high quality, and without domain boundaries.

Preferably, the buffer thin film is of Fe, Co, Ni, Cu, Mo, Ru, Rh, Pd, W, Re, Ir or Pt, or an alloy thereof. Solubility of carbon in these transition metals is lower than in Ni, and hence the carbon that is supplied during film formation does not dissolve in the metal, but grows two-dimensionally as a crystal. Graphene of higher crystallinity can be obtained as a result.

In particular, solubility of carbon in Cu(111) and Ir(111) is low, and hence the latter are particularly preferred, since they do not give rise to precipitation through carbon supersaturation, and therefore allow controlling the number of layers of graphene on the basis of the amount of carbon that is supplied.

The present invention precludes the formation of grain boundaries, which was not possible previously, while preserving a high film quality of monolayer graphene.

The crystal orientation of the buffer thin film on which graphene is grown has the same symmetry as that of graphene, and mismatch is small, of 1.2%. Even upon growth of domain-like graphene, therefore, the domains are joined to each other regularly, without defect intrusion, and graphene can grow while domains combine into one domain.

### BRIEF DESCRIPTION OF THE DRAWINGS

The foregoing advantages and features of the invention will become apparent upon reference to the following detailed description and the accompanying drawings, of which:

FIG. 1 is a conceptual diagram of a multilayer structure of graphene/buffer thin film/Ni(111) single-crystal substrate;

FIG. 2 is a conceptual diagram of a multilayer structure of graphene/buffer thin film/Ni(111) single-crystal thin film/Al₂O₃(0001) single-crystal substrate; and

FIG. 3 is a diagram illustrating domain sizes of graphene produced in accordance with the method of the present invention and in accordance with a conventional method.

### DETAILED DESCRIPTION OF SPECIFIC EMBODIMENTS

### Embodiment 1

Graphene in the present invention is obtained by epitaxially growing a transition metal single-crystal thin film having three-fold symmetry or six-fold symmetry on Ni(111), which has three-fold symmetry, and by epitaxially growing graphene on the surface of the transition metal single-crystal thin film.

The method for epitaxially growing graphene may be a film formation method such as CVD or PVD (physical vapor deposition).

Epitaxial growth of the buffer thin film is accomplished, for instance, by vapor deposition, sputtering, molecular beam epitaxy (MBE) or pulse laser deposition (PLD), in ultra-high vacuum not higher than 1×10⁻⁷ Pa. A transition metal film is formed on Ni(111) at room temperature. Thereafter, annealing is performed at a temperature ranging from 600° C. to 800° C. A buffer thin film can be formed as a result through monocrystallization of the transition metal according to solid-phase epitaxy.

The thickness of the buffer thin film ranges preferably from 2 nm to 100 nm, and more preferably, in particular, from 5 nm to 30 nm, since crystallinity and surface planarity are enhanced in such a case.

A thickness of buffer thin film of 2 nm or less is undesirable, since this precludes formation of a film that covers one face of the substrate, and it becomes difficult to form an atomically flat thin film. Epitaxial growth of 100 nm or more is likewise difficult, and lattice mismatch with graphene increases.

To grow graphene by CVD, a hydrocarbon gas such a methane or the like is blown onto the surface of the buffer thin film, under various conditions, for instance ultra-high vacuum up to 1×10⁻⁷ Pa, low pressure from about 1×10⁻⁶ Pa to 10000 Pa, and atmospheric pressure, and carbon atoms are supplied to the surface through cracking (dissociative adsorption) of the methane.

Under the catalytic effect of the transition metal buffer surface, the carbon atoms migrate over long distances, and reach as a result the ends of the atomic steps. Graphene grows two-dimensionally, in a layer-by-layer fashion. Layer-by-layer growth is required in order to produce high-quality uniform monolayer graphene.

Graphene also can be grown by PVD growth such as MBE, PLD or the like. In MBE, atomic carbon is generated through heating of graphite at a temperature from 1200 to 2000° C. in ultra-high vacuum not higher than 1×10⁻⁷ Pa, and a molecular beam of atomic carbon is supplied to the heated transition metal buffer surface, as a result of which atomic carbon undergoes layer-by-layer growth on the surface. A high-quality graphene film can be formed in this way.

In PLD, graphite is ablated using a KrF excimer laser in an ultra-high vacuum not higher than 1×10⁻⁷ Pa, to instantly eject thereby carbon that is supplied, in the form of a molecular beam, to the heated buffer thin film. A high-quality monolayer graphene film can be formed through layer-by-layer growth in this fashion.

The buffer thin film must be of a form that exhibits three-fold symmetry or six-fold symmetry, which stands in an epitaxial relationship with the crystal structure of graphene, and the surface of the buffer thin film must be atomically flat. Atomically flat denotes herein that the surface of the thin film is flat at the atomic level. Accordingly, the surface roughness of the buffer thin film must be no greater than 1 nm.

### EXAMPLES

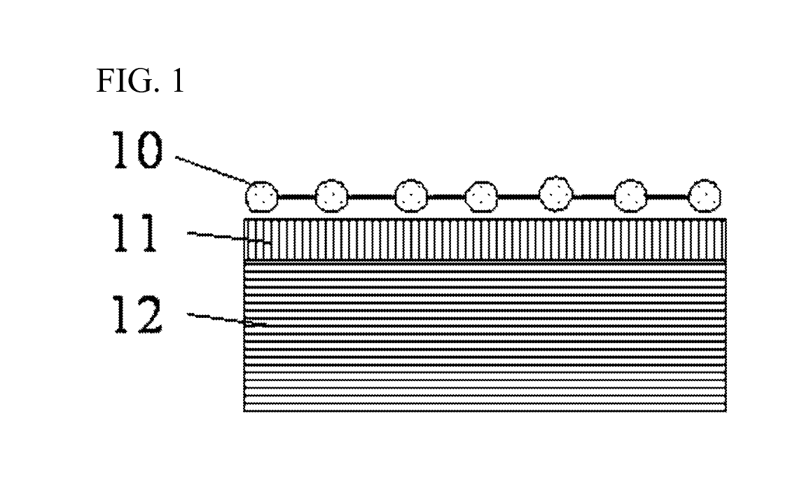

As illustrated in FIG. 1, Ni single-crystal substrate 12 of 10 cm square was set in an MBE apparatus at a degree of vacuum of 5×10⁻⁸ Pa. Thereafter, Ni single-crystal substrate 12 was heated up to 800° C. That temperature was held for 1 hour and was then returned to room temperature. This was followed by several repeated rounds of surface cleaning by Ar ion sputtering and annealing at 800° C., to form thereby an atomically flat surface. With the Ni single-crystal substrate heated at 400° C., a 10 nm film of Ir having a purity of 99.999% was formed by PLD, at a growth rate of 0.1 nm/min, through ablation of an Ir polycrystalline target using a KrF excimer laser. This was followed by 30 minutes of annealing at 800° C., to form Ir(111), and yield a buffer thin film 11.

Then methane at 1×10⁻⁶ Pa was supplied for 10 minutes, with the buffer thin film kept at 600° C., to grow thereby, by CVD, monolayer graphene of Example 1.

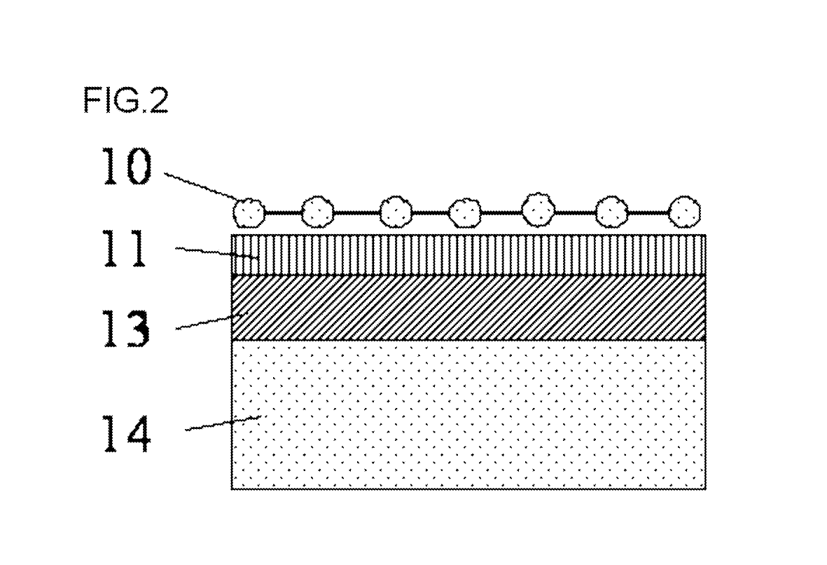

As illustrated in FIG. 2, a 30 nm Ni film was formed, by PLD at room temperature, on Al₂O₃(0001) single-crystal substrate 14, followed by annealing at 800° C. to elicit epitaxial crystallization on the substrate and yield Ni single-crystal thin film 13. Monolayer graphene of Example 2 was then formed under the same conditions as in Example 1, except that Ni single-crystal thin film 13 was used as the substrate.

In Comparative Example 1, a Cu foil was set in a reactor that was evacuated down to 1×10⁻³ Pa. This was followed by heating to 1000° C. at a rate of 50° C./min, in a state where hydrogen at 6.7×10² Pa (5 Torr) was introduced in the reactor. With the temperature held at 1000° C., supply of hydrogen was discontinued next, and methane was introduced at about 4.0×10³ Pa (about 30 Torr). Film formation proceeded for 30 minutes while the substrate temperature and the gas pressure were held. Film formation was followed by quenching at 100° C./second. Graphene was grown as a result.

In Comparative Example 2, monolayer graphene was formed under the same conditions as in Example 1, but using an Al₂O₃(0001) single-crystal substrate as a substrate.

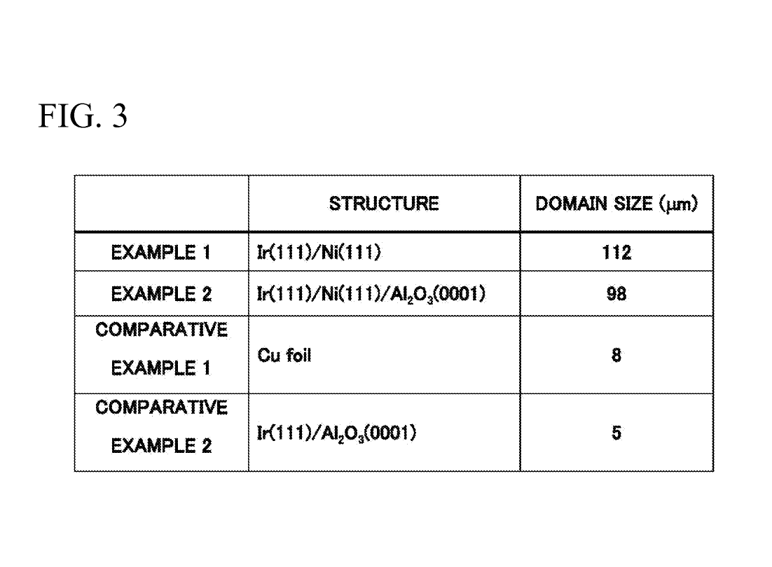

FIG. 3 illustrates domain sizes of monolayer graphene 10 obtained in accordance with the present method. The domain size of graphene in Examples 1 and 2 was very large, of about 100 μm, and an increase in domain size was observed that was ten-fold or greater as compared with that of the Cu foil of Comparative Example 1 or the Ir(111)/Al₂O₃(0001) single-crystal substrate of Comparative Example 2.

The crystal orientation in the Cu foil is not uniform, and domain size is accordingly small. The symmetry of Ir(111)/Al₂O₃(0001) is identical to that of graphene, and carbon solubility is low. However, mismatch is substantial, and domain boundaries are formed as domains of graphene that grows at various sites become joined to each other irregularly. Domain size is accordingly small.

The above results demonstrate the effect of the present invention.

Thus, a method of producing graphene, and the graphene produced by the method, have been described according to the present invention. Many modifications and variations may be made to the techniques and structures described and illustrated herein without departing from the spirit and scope of the invention. Accordingly, it should be understood that the methods and materials described herein are illustrative only and are not limiting upon the scope of the invention.

### EXPLANATION OF REFERENCE NUMERALS

10 graphene (monolayer graphene)
11 buffer thin film
12 Ni(111) single-crystal substrate
13 Ni(111) single-crystal thin film
14 Al₂O₃(0001) single-crystal substrate

What is claimed is:

1. A method for producing graphene in which graphene is formed by supplying carbon to a heated transition metal surface, the method comprising:
providing a Ni(111) substrate;
epitaxially growing a buffer thin film on the Ni(111) substrate, and
forming graphene on the buffer thin film.

2. The method for producing graphene according to claim 1, wherein the buffer thin film is made of material selected from the group consisting of Fe, Co, Ni, Cu, Mo, Ru, Rh, Pd, W, Re, Ir and Pt, or from alloys thereof.

3. The method for producing graphene according to claim 1, wherein the buffer thin film has a surface of three-fold symmetry or six-fold symmetry.

4. The method for producing graphene according to claim 1, wherein the thickness of the buffer thin film ranges from 2 nm to 100 nm.

5. The method for producing graphene according to claim 4, wherein the surface roughness of the buffer thin film is no greater than 1 nm.

6. Graphene which has been formed on a buffer layer that is epitaxially grown on a Ni(111) substrate.

7. The graphene according to claim 6, wherein the buffer thin film is made of material selected from the group consisting of Fe, Co, Ni, Cu, Mo, Ru, Rh, Pd, W, Re, Ir and Pt, or from alloys thereof.

8. The graphene according to claim 6, wherein the buffer thin film has a surface of three-fold symmetry or six-fold symmetry.

9. The graphene according to claim 6, wherein the thickness of the buffer thin film ranges from 2 nm to 100 nm.

10. The graphene according to claim 9, wherein the surface roughness of the buffer thin film is no greater than 1 nm.

11. The method for producing graphene according to claim 2, wherein the buffer thin film has a surface of three-fold symmetry or six-fold symmetry.

12. The method for producing graphene according claim 2, wherein the thickness of the buffer thin film ranges from 2 nm to 100 nm.

13. The method for producing graphene according claim 3, wherein the thickness of the buffer thin film ranges from 2 nm to 100 nm.

14. The method for producing graphene according to claim 12, wherein the surface roughness of the buffer thin film is no greater than 1 nm.

15. The method for producing graphene according to claim 13, wherein the surface roughness of the buffer thin film is no greater than 1 nm.

16. The graphene according to claim 7, wherein the buffer thin film has a surface of three-fold symmetry or six-fold symmetry.

17. The graphene according to claim 7, wherein the thickness of the buffer thin film ranges from 2 nm to 100 nm.

18. The graphene according to claim 8, wherein the thickness of the buffer thin film ranges from 2 nm to 100 nm.
